(19) United States
(12) Patent Application Publication
(10) Pub. No.: US 2026/0036900 A1
(43) Pub. Date: Feb. 5, 2026

(54) MASK INSPECTION DEVICE AND METHOD FOR ADJUSTING A MASK INSPECTION DEVICE

(71) Applicant: Carl Zeiss SMT GmbH, Oberkochen (DE)

(72) Inventors: Lutz Brekerbohm, Hardegsen (DE); Robert Roeder, Jena (DE)

(21) Appl. No.: 19/262,590

(22) Filed: Jul. 8, 2025

(30) Foreign Application Priority Data
Aug. 2, 2024 (DE) 102024122134.8

(51) Int. Cl. G03F 1/84; G03F 1/22

(52) U.S. Cl. CPC G03F 1/84; G03F 1/22

(57) ABSTRACT

A mask inspection device, comprising a vacuum housing, an EUV camera and, arranged in the interior of the vacuum housing, a projection lens for imaging at least one portion of an EUV photomask onto an image sensor of the EUV camera. The EUV camera is mounted on the vacuum housing. The mask inspection device comprises an actuator for adjusting the position of the EUV camera, wherein the actuator acts on a conversion member arranged between the vacuum housing and the EUV camera. The conversion member converts an actuation travel of the actuator into an adjusting travel of the EUV camera, wherein the actuation travel is longer than the adjusting travel. The invention also relates to a method for adjusting a mask inspection device.

### CROSS-REFERENCE TO RELATED APPLICATION

The present application claims the priority of the German patent application DE 10 2024 122 134.8, filed on Aug. 2, 2024, the entire contents of which are incorporated herein by reference.

### TECHNICAL FIELD

The invention relates to a mask inspection device and a method for adjusting a mask inspection device.

### BACKGROUND

Photomasks are used in microlithographic projection exposure apparatuses used to produce integrated circuits with particularly small structures. The photomask illuminated by very short-wave extreme ultraviolet radiation (EUV radiation) is imaged onto a lithography object in order to transfer the mask structure to the lithography object.

To ensure a high quality of the imaging generated on the lithography object, it is necessary for the photomask to be true to size and not adversely affected by contaminations. It is known practice to subject photomasks to an inspection, either prior to operation in a microlithographic projection exposure apparatus or during an interruption of operation. For this purpose, a so-called aerial image of a portion of the photomask is generated, in which case the photomask is imaged onto an EUV image sensor of an EUV camera, rather than onto a lithography object. Using the imaging onto the EUV image sensor as a basis, it is possible to make an assessment as to whether the photomask is without defects and contaminations.

The examination is usually carried out in a mask inspection device suitable for photomasks. The mask inspection device comprises a vacuum housing, within which a projection lens defines an imaging beam path extending from the photomask as far as the image sensor of the EUV camera. It has proved to be expedient to design the mask inspection device such that the EUV camera is mounted on the vacuum housing. However, it is then not a straightforward matter to adjust the mask inspection device so as to result in entirely satisfactory imaging of the photomask onto the image sensor of the EUV camera.

### SUMMARY

The invention is based on the aspect of presenting a mask inspection device and a method for adjusting a mask inspection device which reduce the disadvantages mentioned. The aspect is achieved by the features of the independent claims. Advantageous embodiments are specified in the dependent claims.

In some implementations, a mask inspection device according to the invention comprises a vacuum housing, an EUV camera and, arranged in the interior of the vacuum housing, a projection lens for imaging a portion of an EUV photomask onto an image sensor of the EUV camera. The image sensor can include, e.g., a charge coupled device (CCD) sensor or a complementary metal oxide semiconductor (CMOS) sensor having an array of independently addressable sensing elements or pixels. The EUV camera is mounted on the vacuum housing. The mask inspection device comprises an actuator for adjusting the position of the EUV camera, wherein the actuator acts on a conversion member arranged between the vacuum housing and the EUV camera. The conversion member converts an actuation travel of the actuator into an adjusting travel of the EUV camera, wherein the actuation travel is longer than the adjusting travel.

The invention is based on the insight that it is not a straightforward matter to adjust the imaging beam path between the photomask and the image sensor of the EUV camera by adjusting optical elements of the projection lens. According to the invention, the imaging beam path can be adjusted by way of changing the position of the EUV camera relative to the vacuum housing.

The invention proposes arranging a conversion member between the EUV camera and the vacuum housing, such that the actuation force exerted by an actuator can be transmitted to the EUV camera via the conversion member. The conversion member is designed to convert a larger actuation travel of the actuator into a smaller adjusting travel of the EUV camera. This makes it possible for the considerable forces required for moving the EUV camera to be applied using an actuator having small dimensions. The conversion member can be supported on the EUV camera and on the vacuum housing. The state of the conversion member can change upon actuation of the actuator, with the result that the distance between the vacuum housing and the EUV camera is set.

The conversion member can be a hydraulic conversion member. The conversion member can have an interior filled with a hydraulic liquid. The interior can be delimited by an input piston and an output piston, such that a movement of the input piston along an actuation travel is transformed into a movement of the output piston via the hydraulic liquid. The interior can be closed off, moreover, such that the movement of the input piston and the movement of the output piston directly correspond to one another.

The conversion member can have a conversion ratio of at least 1:10, preferably of at least 1:20, with further preference of at least 1:50. Given such a conversion ratio, the actuation travel of the input piston is longer than the adjusting travel of the output piston by at least a factor of 10, 20 or 50.

The direction of movement of the output piston can form an angle of at least 80°, preferably of at least 85°, with further preference of at least 89°, with the plane of the EUV image sensor. In the case of such a design, the conversion member can influence the distance between the EUV image sensor and the vacuum housing. The adjusting travel of the output piston can form an angle of between 30° and 150°, preferably between 60° and 120°, with further preference between 80° and 100°, with the actuation travel of the input piston. In this way, the actuation of the conversion member can be facilitated if the available space in the direction of movement of the output piston is limited.

The conversion member can be designed such that it acts exclusively with pressure. This means that a transmission of tensile forces between the EUV camera and the vacuum housing is not possible. For this purpose, it is advantageous if the weight force of the EUV camera acts against the conversion member. The adjusting travel of the conversion member can form an angle of not more than 10°, preferably of not more than 5°, with further preference of not more than 1°, with the vertical. The mask inspector device can be designed such that the EUV camera can be lifted off the conversion member without the need to release securing elements that exist between the EUV camera and the conversion member.

A clean room atmosphere can be present outside the vacuum housing. Since customary hydraulic oils entail a risk of contaminations of the clean room atmosphere, an oil-free hydraulic liquid can be used in the case of the conversion member according to an example of the invention. The hydraulic liquid can be for example water, in particular deionized water.

The actuator can be designed to exert a force in a linear direction on the conversion member in order to actuate the conversion member. The actuator can comprise a drive motor and a gear mechanism, wherein the gear mechanism is designed to convert a rotational movement of the drive motor into a linear movement. The conversion between the rotational movement and the linear movement can be effected for example via a toothed rack or via a thread mechanism. In one embodiment, the actuator is self-locking. This means that the actuator maintains its current position without energy being externally supplied to the actuator. In particular, the self-locking has the effect that the actuator remains in its position when a force is exerted on the actuator via the conversion member.

The invention encompasses embodiments in which the conversion member is not a hydraulic conversion member. By way of example, the conversion member can comprise a lever mechanism or a thread mechanism in order to bring about the conversion.

The actuator unit composed of the actuator and the conversion member can be designed to exert a force of at least 500 kg. preferably of at least 1000 kg. with further preference of at least 2000 kg, between the vacuum housing and the EUV camera. This indication relates to the weight force that would be exerted by a body having the relevant mass. The adjusting travel made available by the combination of the actuator and the conversion member can be for example between 0.05 mm and 0.5 mm, preferably between 0.1 mm and 0.3 mm.

The mask inspection device can have at least two conversion members, preferably at least three conversion members, between the EUV camera and the vacuum housing. The adjusting travels of the conversion members can be parallel to one another for the plurality of conversion members. In particular, the adjusting travel of the conversion members can be vertical, i.e. parallel to the gravitational force. Each of the conversion members can be assigned an actuator, such that the conversion members can be actuated independently of one another.

Parallel actuation of the conversion members makes it possible to change the distance between the EUV camera and the vacuum housing. In this case, the angular orientation of the EUV camera relative to the vacuum housing can remain unchanged. If only individual conversion members are actuated or a plurality of conversion members are actuated in opposite directions, the angular orientation between the EUV camera and the vacuum housing can be changed. The conversion members can be arranged such that the EUV camera can be tilted in any direction relative to the vacuum housing.

The mask inspection device can comprise a control unit designed to generate control signals used to control the actuators. The control unit can be designed to process input variables in order to generate the control signals for the actuators. The input variables can be manual inputs. It is also possible to process input variables that were generated in an automatic process. The input variables can be fed to the control unit by way of data transfer.

In one embodiment, the control unit is an element of a closed control loop. In the closed control loop, the control unit can process a measured value regarding the position of the EUV camera as input variable. In one embodiment, a measured value regarding the position relative to the vacuum housing is processed. The measured value can represent the angle between the Z-direction and the plane of the image sensor of the EUV camera. Z-direction denotes the direction of the optical axis of the imaging beam path of the projection lens in a portion adjacent to the EUV image sensor. In addition or as an alternative thereto, the measured value can represent the distance between an image plane of the imaging beam path and the position of the image sensor in the Z-direction. The measurement can comprise the position of the EUV camera in one or more degrees of freedom, in particular in six degrees of freedom. In one embodiment, the number of degrees of freedom of the measurement corresponds to the number of degrees of freedom which can be realized with the conversion members present. It is possible to process a plurality of measured values as input variables in the control unit, which concern various parameters of the position of the EUV camera relative to the vacuum housing. The control unit can be designed to determine the control commands for the actuators such that the difference between an actual position represented by the measured values and a target position is reduced. In addition or as an alternative thereto, it is also possible to process measured values representing the position of the EUV camera relative to the projection lens. The specifications applicable to the number of degrees of freedom of the measurement can be the same as those for a measurement of the position relative to the vacuum housing.

An adjusting process according to the invention can be carried out during the initial start-up of the mask inspection device in order to adjust the position of the EUV camera relative to the vacuum housing to a basic state. In addition or as an alternative thereto, an adjusting process according to the invention can be carried out during operation in order to adjust the position of the EUV camera relative to the vacuum housing between a preceding first operating phase and a succeeding second operating phase. Such an adjusting process can be carried out during a pause in operation for the mask inspection device or during ongoing operation.

In one embodiment, the mask inspection device comprises an adjusting device, which makes it possible to change the position of the EUV camera relative to the vacuum housing while the state of the conversion member remains unchanged. The adjusting device can have an adjusting travel that is greater than the adjusting travel of the conversion member. The adjusting travel of the adjusting device can be between 0.5 mm and 2 mm, for example. The adjusting device can be used during the initial start-up of the mask inspection device in order to adjust the position of the EUV camera relative to the vacuum housing. The conversion members according to the invention can be used to adjust the position of the EUV camera relative to the vacuum housing during operation of the mask inspection device. That is based on the consideration that an adjusting travel required for adjusting the mask inspection apparatus is often larger during the initial start-up compared with a readjustment during operation.

The photomask can be arranged inside the vacuum housing during the inspection process. The vacuum housing can be designed for a high vacuum. The pressure in the vacuum housing during operation of the mask inspection device can be for example between 10⁻⁶ mbar and 10⁻⁹ mbar, preferably between 10⁻⁷ and 10⁻⁸ mbar. A pressure difference corresponding to the difference between the pressure in the interior of the vacuum housing and atmospheric pressure can be present across the wall of the vacuum housing. The wall of the vacuum housing can be provided with a closable opening designed to make it possible to change the photomask between an interior and an exterior of the vacuum housing.

The vacuum housing can have an opening to which the EUV camera is connected. The interior of the vacuum housing can be closed off by the EUV camera, such that the pressure difference present across the EUV camera is the same as that present across other regions of the vacuum housing. The opening of the vacuum housing can be vacuum-tightly sealed when the EUV camera is mounted on the vacuum housing. In this state, the image sensor of the EUV camera can be arranged in the interior of the vacuum chamber. A housing part of the EUV camera can form a portion of the wall of the vacuum housing. The vacuum housing can have a flange which surrounds the opening and on which the EUV camera can be mounted. The pressure difference present across the EUV camera can be the same as that present across the vacuum housing. In other words, there is a first region of the EUV camera, which is exposed to the interior of the vacuum housing, and a second region of the EUV camera, which is exposed to the surroundings.

A flexible wall portion can be formed between the EUV camera and the vacuum housing, and is subjected to a deformation when the position of the EUV camera is adjusted relative to the vacuum housing. The flexible wall portion can terminate in a vacuum-tight fashion with the housing of the EUV camera and terminate in a vacuum-tight fashion with the vacuum housing. The pressure difference present across the flexible wall portion can be the same as that present across other portions of the wall of the vacuum chamber. The flexible wall portion can be configured for example as bellows or as a membrane. The conversion member and/or the actuator can be arranged outside the vacuum housing, such that these components are not exposed to the vacuum conditions.

Components of the EUV camera can be temperature-regulated to a temperature that deviates from the temperature in the interior of the vacuum chamber and from the ambient temperature. In particular, components of the EUV camera can be cooled to a temperature that is lower than these temperatures. For the heat transfer required for such temperature-regulation, it is advantageous if the housing of the EUV camera forms part of the vacuum housing. Externally accessible parts of the camera housing can then be used for the heat transfer.

The mask inspection device can have a frame structure arranged in the vacuum housing, said frame structure carrying the optical components of the projection lens. The frame structure can be mechanically decoupled from the vacuum housing. As a result, the vacuum housing can deform, without mechanical stresses being transferred to the frame structure. A connection between the EUV camera and the frame structure can exist via the vacuum housing, on which both the frame structure and the EUV camera are mounted. In the case of such a design, it may transpire that the EUV camera changes its position relative to the frame structure as a result of the effect of disturbing influences. These may be for example thermal influences, dynamic influences, pressure differences or tolerances. The invention opens up the possibility of compensating for such changes in position by adapting the position of the EUV camera relative to the vacuum housing.

The mask inspection device can comprise an illumination system, which guides EUV radiation emerging from an EUV radiation source onto a photomask arranged in the interior of the vacuum housing. The illumination system can be configured such that the photomask is illuminated with uniform brightness. The optical components of the illumination system can be mounted on the frame structure. The projection lens, the illumination system and the frame structure can form a mechanical unit in this way. The projection lens of a mask inspection device is generally designed to generate a magnified imaging of a portion of a photomask on the EUV image sensor. The magnification factor can be greater than 20, preferably greater than 50, more preferably greater than 100.

An EUV camera according to the invention can have significantly larger dimensions than commercially available photographic cameras. The weight of the camera can be for example higher than 20 kg, preferably higher than 50 kg, more preferably higher than 100 kg. The image sensor of the camera can have the shape of an approximately rectangular array. One of the edge lengths of the rectangle spanned by the array can be between 100 mm and 200 mm, for example. An opening in the vacuum housing via which the EUV camera is mounted on the vacuum housing can have a surface area of between 0.2 m² and 1 m², preferably between 0.3 m² and 0.7 m². If the EUV camera is arranged on top of the vacuum housing, the weight force of the EUV camera is added to a force exerted by the pressure difference across the camera housing, such that forces needed to be overcome for moving the EUV camera are significantly higher than the pure weight force.

In some implementations, the invention relates to a method for adjusting a mask inspection device, wherein the mask inspection device comprises a vacuum housing, an EUV camera and, arranged in the interior of the vacuum housing, a projection lens for imaging a portion of an EUV photomask onto an image sensor of the EUV camera, and wherein the EUV camera is mounted on the vacuum housing. The position of the EUV camera is adjusted by an actuator. The actuator acts on a conversion member arranged between the vacuum housing and the EUV camera. The conversion member converts an actuation travel of the actuator into an adjusting travel of the EUV camera, wherein the actuation travel is longer than the adjusting travel.

The disclosure encompasses developments of the method with features which are described in the context of the mask inspection device according to the invention. The disclosure encompasses developments of the mask inspection device with features which are described in the context of the method according to the invention.

### BRIEF DESCRIPTION OF DRAWINGS

The invention is described by way of example below on the basis of advantageous embodiments with reference to the accompanying drawings, in which:

FIG. 1: shows a schematic illustration of an example of a mask inspection apparatus according to the invention;

FIG. 2: shows a schematic illustration of an example of a photomask;

FIG. 3: shows a schematic sectional illustration of an example of an EUV camera;

FIG. 4: shows an aspect of an example of a mask inspection apparatus according to the invention;

FIG. 5: shows a detail from FIG. 4 in a schematic illustration;

FIG. 6: shows the view in accordance with FIG. 5 in an alternative embodiment of the invention;

FIGS. 7, 8: show alternative embodiments of the invention.

### DETAILED DESCRIPTION

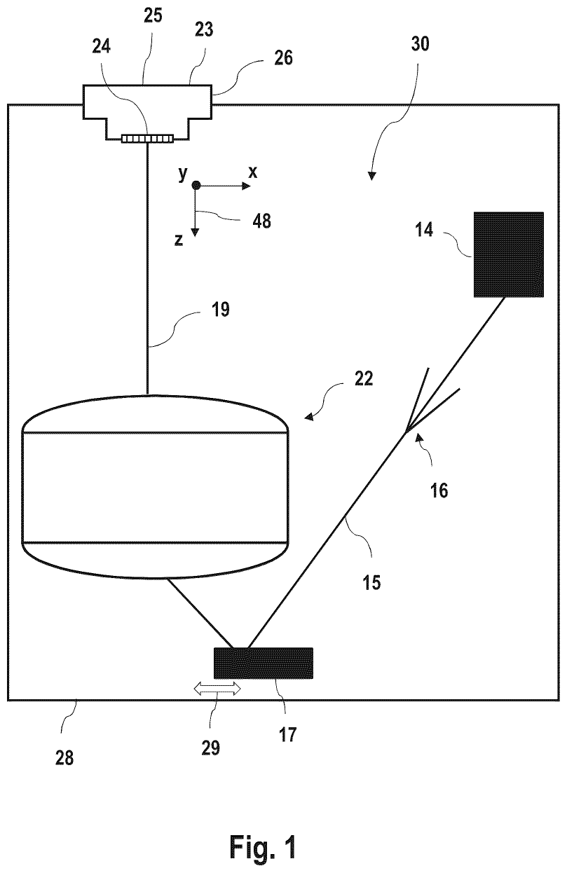

Microlithographic photomasks 17 can be examined by use of a mask inspection apparatus shown in FIG. 1.

In general, microlithographic photomasks 17 are intended to be used in a microlithographic projection exposure apparatus (not illustrated). In the microlithographic projection exposure apparatus, the photomask 17 is illuminated with extreme ultraviolet radiation (EUV radiation) at a wavelength of for example 13.5 nm in order to image a structure formed on the photomask 17 onto the surface of a lithographic object in the form of a wafer. The wafer is coated with a photoresist that reacts to the EUV radiation. The mask inspection apparatus is used to examine whether the photomask meets the requirements and is free from contamination.

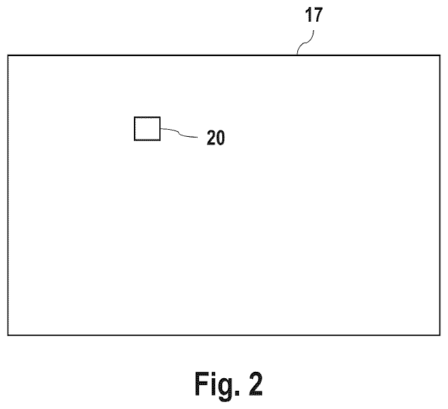

In accordance with FIG. 1, the photomask 17 is arranged in the mask inspection apparatus such that an EUV beam path 15 emanating from an EUV radiation source 14 is guided via an illumination system 16 to the photomask 17. The illumination system 16 is used to shape the EUV radiation to form a beam used to illuminate, with uniform brightness, an examination field on the surface of the photomask 17. The examination field 20, which is small in comparison with the area of the photomask 17, is depicted in FIG. 2 in an illustration that is not true to scale. The illuminated region 20 can have dimensions of 0.5 mm×0.8 mm, for example. The edge lengths of the photomask 17 can be between 100 mm and 200 mm, for example. A field stop used to delimit the illuminated region to the examination field 20 on the surface of the photomask 17 is arranged in the illumination system 16. Using a positioning mechanism 29, it is possible to move the photomask 17 in the horizontal plane in order to bring different examination fields 20 into the region of the EUV beam path.

The photomask can have for example an aspect ratio of between 1:1 and 1:3, preferably between 1:1 and 1:2 and particularly preferably of 1:1 or 1:2. The photomask can be configured in a substantially rectangular fashion. The photomask can preferably have a length and a width of 5 to 7 inches (12.7 cm to 17.8 cm), particularly preferably a length and a width of 6 inches (15.2 cm). As an alternative thereto, the photomask can have a length of 5 to 7 inches (12.7 cm to 17.8 cm) and a width of 10 to 14 inches (25.4 cm to 35.6 cm), preferably a length of 6 inches (15.2 cm) and a width of 12 inches (30.5 cm).

The EUV beam path 15 reflected at the photomask 17 continues through a projection lens 22 to an EUV camera 23, which is equipped with an image sensor 24. The projection lens is used to image the examination field 20 of the photomask 17 onto the image sensor 24 of the EUV camera 23. The imaging beam path 19 is incident on the image sensor 24 in the Z-direction 48. The EUV radiation source 14, the illumination system 15, the photomask 17, the projection lens 22 and the image sensor 24 of the EUV camera 23 are arranged in a vacuum chamber 30 surrounded by a vacuum housing 28. During operation of the mask inspection apparatus, a high vacuum is present in the vacuum chamber by using, e.g., a vacuum pump. The EUV camera 23 comprises a camera housing 25, which carries the image sensor 24. A rear-side part 26 of the camera housing 25 projects out of the vacuum housing 28, while the image sensor 24 is exposed to the vacuum in the vacuum housing 28. The camera housing 25 accordingly forms part of the vacuum housing 28 and is exposed to the same pressure difference as other wall regions of the vacuum chamber 30.

The EUV radiation source 14 is a plasma radiation source, in which the EUV radiation is emitted from a plasma at a wavelength of 13.5 nm. Tin is a medium that can be used to generate a plasma suitable for emitting such EUV radiation. A laser beam can be made to impinge on a droplet of the medium for the purpose of generating the plasma.

The mirrors in the illumination system 16 and the mirrors in the projection lens 22 are designed as EUV mirrors which have a particularly high reflectivity for EUV radiation. The optical area of the EUV mirrors can be formed by a highly reflective coating. This can be a multilayer coating, in particular a multilayer coating having alternating layers of molybdenum and silicon. Using such a coating, it is possible to reflect approximately 70% of the incident EUV radiation.

The projection lens 22 has a magnification factor of more than 100. In order to be able to record the entirety of the image generated by the examination field 20 of the photomask 17, the area of the image sensor 24 is greater than the area of the examination field 20 in accordance with the magnification factor. The image sensor 24 can have dimensions of the order of magnitude of 100 mm to 200 mm, for example.

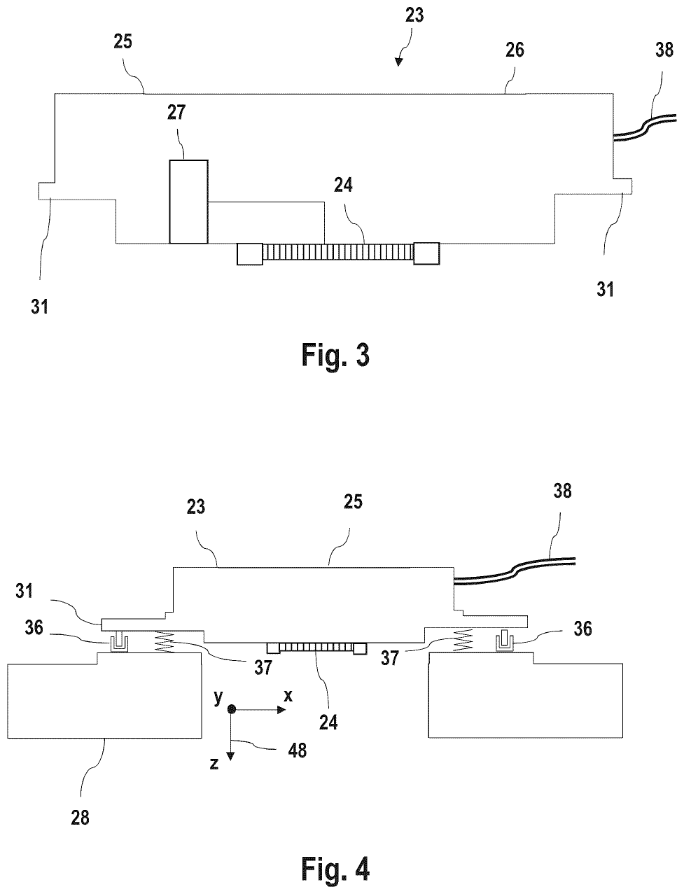

In accordance with FIG. 3, the EUV camera 23 comprises a housing 25, on which the image sensor 24 and an electronics unit 27 are arranged. By use of the electronics unit 27, the image sensor 24 is controlled, and the EUV image data obtained by the image sensor 24 are processed and output as sensor data. Via supply lines 38, the EUV camera 23 is supplied with electrical energy, the sensor data are transferred and a cooling device (not illustrated) is operated, by means of which components of the EUV camera 23 are cooled to a desired temperature.

A vacuum flange 31 is formed on the camera housing 25, and extends without interruption over the periphery of the camera housing 25. A connection between the EUV camera 23 and the vacuum housing 28 is established via the vacuum flange 31. In the connected state, the rear side 26 of the camera housing 25 together with the vacuum housing 28 forms a portion of the wall of the vacuum chamber 30.

In accordance with FIG. 4, a plurality of actuator units 36 are arranged between the EUV camera 23 and the vacuum housing 28. The interspace between the flange 31 of the EUV camera 23 and the vacuum housing 28 is sealed via a flexible wall portion in the form of bellows 37. The bellows 37 extend without interruption over the periphery of the EUV camera 23. The vacuum housing 28, the camera housing 25 and the bellows 37 form portions in the wall of the vacuum chamber 30 across which the pressure difference between the high vacuum in the interior of the vacuum chamber 30 and the atmospheric pressure in the surroundings is present.

In some implementations, the EUV camera 23 and the vacuum housing 28 are held at a distance from one another by four actuator units 36, wherein the two actuator units 36 that are visible in FIG. 4 are spaced apart from one another in the X-direction, and wherein the two actuator units 36 that are not visible in FIG. 4 are spaced apart from one another in the Y-direction. The actuator units 36 can be adjusted in length independently of one another, as a result of which the distance between the EUV camera 23 and the vacuum housing 28 can be changed. The actuator units 36 are arranged radially outside the bellows 37, such that the actuator units 36 are exposed to atmospheric pressure.

Suitable control of the actuator units 36 makes it possible to adjust the position of the EUV camera 23 relative to the vacuum housing 28. The EUV camera 23 can be tilted about the Y-axis by use of one of the two actuator units 36 that are visible in FIG. 4 being lengthened and the other being correspondingly shortened. The EUV camera 23 can be tilted about the X-axis by use of one of the two actuator units 36 that are not visible in FIG. 4 being lengthened and the other being correspondingly shortened. The EUV camera 23 can be displaced in the Z-direction 48 by use of all four actuator units 36 being jointly lengthened or shortened. The actuator units 36 are controlled by a control unit 39 (not shown in FIG. 4).

The force acting between the EUV camera 23 and the vacuum housing 28 is composed of the weight force of the EUV camera 23 and the force resulting from the pressure difference between the vacuum pressure in the interior of the vacuum chamber 30 and atmospheric pressure. The force resulting from the pressure difference outweighs the weight force considerably, such that overall a force which corresponds to a weight force of several tonnes is produced. The total force is transmitted by way of the actuator units 36. If the position of the EUV camera 23 relative to the vacuum housing 28 is intended to be changed, the actuator units 36 must overcome this force.

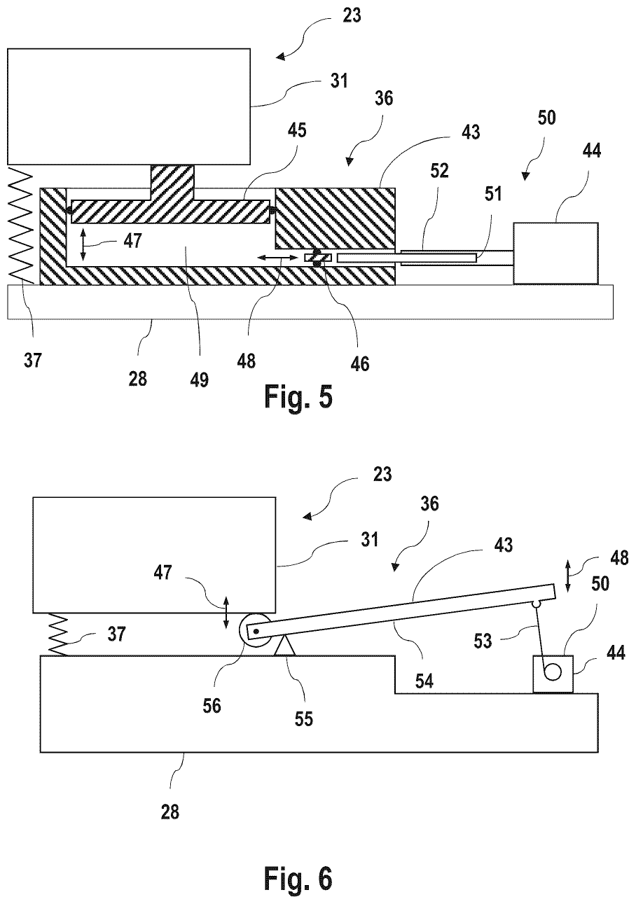

In accordance with FIG. 5, an actuator unit 36 illustrated by way of example comprises an actuator 50 and a conversion member 43. The conversion member 43 has a conversion ratio of more than 1:100, such that a large actuation travel 48 of the actuator 50 results in a small adjusting travel 47 of the EUV camera 23. Conversely, a small force of the actuator 50 is sufficient to overcome the considerable force acting between the EUV camera 23 and the vacuum housing 28.

In some implementations, the conversion member 43 has an interior 49 filled with a hydraulic liquid in the form of deionized water. The cavity 49, which moreover is closed off all around, is delimited by an input piston 46 having a small diameter and by an output piston 45 having a large diameter. The input piston 46 is coupled to the actuator 50, and the output piston 45 is coupled to the EUV camera 23. If the input piston 46 is forced into the interior 49, then the output piston 45 moves upwards and raises the EUV camera 23.

In some implementations, the actuator 50 comprises a spindle mechanism having a spindle sleeve 52 and a spindle rod 51. A drive motor 44 drives a rotational movement of the spindle rod 51, which is converted into a linear movement by a threaded engagement with the spindle sleeve 52. The distal end of the spindle rod 51 acts on the input piston 46. The spindle mechanism is self-locking, such that the spindle mechanism keeps the input piston 46 in its position, without the drive motor 44 exerting a force.

In the alternative embodiment of an actuator unit 36 in FIG. 6, the conversion member 43 comprises a lever arm 54 bearing on a lever point 55. A roller 56 is arranged at a distal end of the lever arm 54, and bears against the bottom of the EUV camera 23. The opposite, proximal end of the lever arm 54 is connected to the drive motor 44 of the actuator 50 via a traction cable 53. If the traction cable 53 is hauled in by actuation of the drive motor 44, then the EUV camera 23 is raised via the roller 56. Such a lever mechanism is also suitable for overcoming the considerable forces between the EUV camera 23 and the vacuum housing 28.

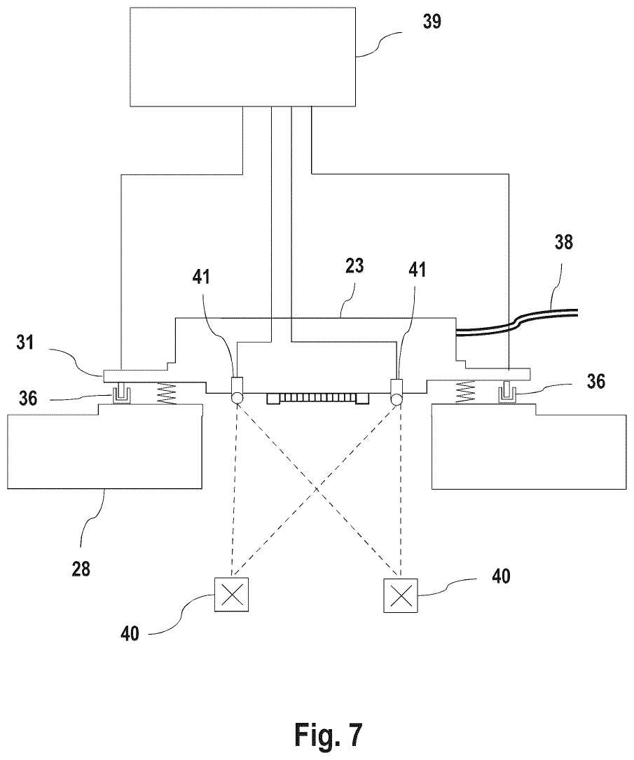

FIG. 7 illustrates a variant in which the EUV camera 23 is equipped with a plurality of distance sensors 41. The distance sensors 41 are designed to measure the distance to targets 40 mounted on the projection lens 22. The measured values from the distance sensors 41 are processed in the control unit 39 in order to determine whether the EUV camera 23 has the correct position relative to the projection lens 22. If this is not the case, the control unit 39 transmits control commands to the actuators 36, such that the difference between the actual position determined by the distance sensors 41 and a target position of the EUV camera 23 is reduced. The distance sensors 41, the control unit 39 and the actuators 36 are elements of a closed control loop. The control loop is active during operation of the mask inspection apparatus, such that the position of the EUV camera 23 is constantly adapted to the current conditions.

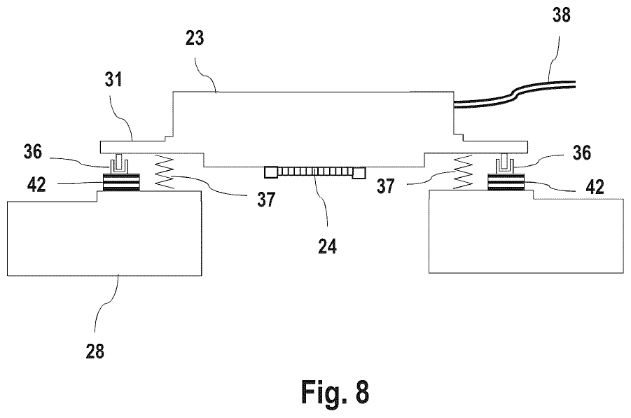

In the embodiment in accordance with FIG. 8, a plurality of spacer washers 42 are arranged between each of the actuator units 36 and the vacuum housing 29. In the course of the initial start-up of the mask inspection device, the number of spacer washers 42 is chosen individually for each of the actuator units 36 so as to result in a basic setting in which the EUV camera 23 has approximately the appropriate alignment relative to the projection lens 22. The further fine setting takes place during operation by way of the actuator units 36. The spacer washers 42 are part of an adjusting device that makes it possible to change the position of the EUV camera relative to the vacuum housing while the state of the conversion member remains unchanged.

A number of embodiments of the invention have been described. Nevertheless, it will be understood that various modifications can be made without departing from the spirit and scope of the invention. For example, the projection lens 22 can include one or more optical lenses, mirrors, filters, and/or stops.

While some embodiments, examples or aspects described herein include some but not other features included in other embodiments, examples or aspects combinations of features of different embodiments, examples or aspects are meant to be within the scope of the claims, and form different embodiments, as would be understood by those skilled in the art. The embodiments of the present invention that are described in this specification and the optional features and properties respectively mentioned in this regard should also be understood to be disclosed in all combinations with one another. The description of a feature comprised by an embodiment-unless explicitly explained to the contrary-should also not be understood such that the feature is essential or indispensable for the function of the embodiment. Accordingly, other embodiments are within the scope of the following claims.

What is claimed is:

1. A mask inspection device, comprising a vacuum housing, an EUV camera and, arranged in the interior of the vacuum housing, a projection lens for imaging a portion of an EUV photomask onto an image sensor of the EUV camera, wherein the EUV camera is mounted on the vacuum housing, further comprising an actuator for adjusting the position of the EUV camera and a conversion member arranged between the vacuum housing and the EUV camera, wherein the actuator acts on the conversion member, wherein the conversion member converts an actuation travel of the actuator into an adjusting travel of the EUV camera, and wherein the actuation travel is longer than the adjusting travel.

2. The mask inspection device of claim 1, wherein the conversion member has a conversion ratio of at least 1:50.

3. The mask inspection device of claim 1, wherein the conversion member is a hydraulic conversion member.

4. The mask inspection device of claim 3, wherein the conversion member comprises an input piston and an output piston and wherein the actuation travel of the input piston forms an angle of between 30° and 150° with the adjusting travel of the output piston.

5. The mask inspection device of claim 3, wherein the hydraulic liquid of the conversion member is an oil-free hydraulic liquid.

6. The mask inspection device of claim 3, wherein the hydraulic liquid of the conversion member is deionized water.

7. The mask inspection device of claim 1, wherein the conversion member is designed such that it acts exclusively with pressure.

8. The mask inspection device of claim 1, wherein the direction of the adjusting travel forms an angle of not more than 10° with the vertical.

9. The mask inspection device of claim 1, wherein a clean room atmosphere is present outside the vacuum housing.

10. The mask inspection device of claim 1, wherein the actuator is self-locking.

11. The mask inspection device of claim 1, wherein the adjusting travel of an actuator unit comprising the conversion member and the actuator is between 0.05 mm and 0.5 mm.

12. The mask inspection device of claim 11, wherein the actuator unit is designed to exert a force of at least 500 kg between the vacuum housing and the EUV camera.

13. The mask inspection device of claim 1, comprising at least two conversion members between the EUV camera and the vacuum housing.

14. The mask inspection device of claim 13, wherein the adjusting travels of the conversion members are parallel to one another.

15. The mask inspection device of claim 13, wherein the conversion members can be actuated independently of one another.

16. The mask inspection device of claim 1, wherein the pressure difference present across the EUV camera is the same as that present across the vacuum housing.

17. The mask inspection device of claim 1, wherein a flexible wall portion is formed between the EUV camera and the vacuum housing, and is subjected to a deformation when the position of the EUV camera is adjusted relative to the vacuum housing.

18. The mask inspection device of claim 1, wherein the conversion member and/or the actuator are/is arranged outside the vacuum housing.

19. A method for adjusting a mask inspection device, wherein the mask inspection device comprises a vacuum housing, an EUV camera and, arranged in the interior of the vacuum housing, a projection lens for imaging a portion of an EUV photomask onto an image sensor of the EUV camera, wherein the EUV camera is mounted on the vacuum housing, wherein the position of the EUV camera is adjusted by an actuator, wherein the actuator acts on a conversion member arranged between the vacuum housing and the EUV camera, wherein the conversion member converts an actuation travel of the actuator into an adjusting travel of the EUV camera, and wherein the actuation travel is longer than the adjusting travel.

20. The method of claim 19, wherein the conversion member has a conversion ratio of at least 1:50.
